(19) United States
(12) Patent Application Publication
(10) Pub. No.: US 2005/0000561 A1
(43) Pub. Date: Jan. 6, 2005

(54) Photovoltaic cell assembly and the method of producing one such assembly

(76) Inventors: Guy Baret, Voiron (FR); Hubert Lauvray, St Clair Du Rhone (FR)

Correspondence Address: OLIFF & BERRIDGE, PLC, P.O. BOX 19928, ALEXANDRIA, VA, 22320, US

(21) Appl. No.: 10/492,906

(22) PCT Filed: Sep. 13, 2002
(86) PCT No.: PCT/FR02/03124

(30) Foreign Application Priority Data
Oct. 30, 2001 (FR) 01/14017

(51) Int. Cl. H01L 25/00

(52) U.S. Cl. 136/244; 438/80

(57) ABSTRACT

The photovoltaic cells (1a, 1b) of the assembly are disposed side by side between a front (10) and rear (11) glass substrates and are connected in series by means of front (12) and (13) rear connecting conductors and of interconnection elements (14). The connecting conductors can be formed on the internal face of each glass substrate facing the location of each of the cells or obtained by laser cutting, through the glass substrates, of conducting strips tightened beforehand between the cells and the glass substrates. The electrical interconnection elements (14) are disposed between two adjacent cells (1) to connect the opposite connecting conductors associated to two adjacent cells. A sealing joint (16), made of inorganic material, arranged between the two glass substrates (10, 11), defines a sealed internal volume which contains all the cells (1). Sealing is performed between 380° C. and 480° C. for a period of less than 30 minutes.

### BACKGROUND OF THE INVENTION

The invention relates to an assembly of photovoltaic cells arranged side by side between front and rear glass substrates and connected in series by front and rear connecting conductors respectively arranged on each side of each of the cells and comprising a connecting zone extending beyond a predetermined side of said location, the assembly comprising electrical interconnection elements arranged between two adjacent cells to connect the opposite connecting zones of the front and rear connecting conductors respectively associated to two adjacent cells.

### STATE OF THE ART

A photovoltaic cell is conventionally formed on a bulk silicon substrate cut into the form of wafers with a thickness of a few hundred microns. The substrate can be made of mono-crystalline silicon, polycrystalline silicon, or semi-conducting layers deposited on a glass or ceramic substrate. It has on its surface a network of narrow electrodes, generally made of silver or aluminium, designed to drain the current to one or more main electrodes with a width of one to a few millimeters, also made of silver or aluminium.

Each cell supplies a current dependent on the lighting in an electrical voltage which depends on the nature of the semi-conductor and which is usually about 0.45V to 0.65V for crystalline silicon. As voltages of 6V to several tens of volts are usually necessary to make electrical apparatuses operate, a photovoltaic module is generally formed by an assembly of several cells in series. A module of 40 cells supplies for example close to 24 volts. Depending on the currents required, several cells can also be placed in parallel. A generator can then be achieved by adding thereto storage batteries, a voltage regulator, etc.

To fabricate a photovoltaic module, the cells are prepared, i.e. covered with a network of electrodes and connected to one another by metal strips. The assembly thus formed is then placed between two polymer sheets themselves clamped between two glass substrates. The assembly is then heated to about 120° C. to soften the polymer greatly, to make it transparent and achieve mechanical cohesion of the module.

A crystalline silicon photovoltaic module thus prepared is illustrated in top view in FIG. 1. The cell 1 comprises on the front face of a silicon substrate, the top face which constitutes its sensitive face, a network of silver electrodes 2 designed to drain the current to connection zones. The latter are formed, in FIG. 1, by two wider electrodes constituting collector buses 3 perpendicular to the electrode network 2. The electrodes 2 are achieved by deposition of a silver paste according to the required pattern, then by annealing at high temperature. Front transverse metal strips 4 formed by a copper body and a superficial deposition of tin-lead alloy are soldered with a tin-lead alloy onto the collector buses 3 of the cell. The rear face of the cell 1 comprises a second electrode network, a network generally denser than the electrode network 2 of the front face. The second electrode network is in like manner connected to rear transverse metal strips 5 by means of collector buses.

FIGS. 2 and 3 respectively illustrate the front face and rear face of a conventional cell before the transverse metal strips 4 and 5 are placed. On the front face, the collector buses 3 and solder studs 6, arranged at regular intervals along the collector buses 3, can be deposited at the same time as the electrode network 2, for example by serigraphy of the silicon substrate. The rear face of the cell can be covered by a layer of aluminium covering practically the whole of the rear surface and constituting the second electrode network, solder tracks 7 being formed beforehand at the locations of the collector buses 3.

FIGS. 4 and 5 respectively illustrate the front face and rear face of a conventional cell after the transverse metal strips 4 and 5 have been placed and fixed by soldering. As represented in FIG. 6, a solder layer (tin/lead) 48 is deposited beforehand between the strips 4 and 5 and the tracks and solder studs.

This type of fabrication process implies a large consumption of very expensive silver- and aluminium-based solder paste. In addition, the collector buses 3 and solder studs 6 cause a large shadow factor on the front face of the cell, thus reducing the power generated by the latter. Furthermore, deposition of the aluminium layer on the surface of the rear face not covered by the solder tracks 7 involves two well-aligned serigraphy or metallization steps. The soldering itself is a costly, mechanically complicated operation requiring the cell to be turned and able to result in non-negligible risks of breakage of the cell. The transverse metal strips 4 and 5 moreover have to be well aligned with the collector buses 3 of the front face and with the solder tracks 7 of the rear face respectively. In case of misalignment, the cell is liable to be destroyed when soldering takes place and the shadow factor on the front face may be increased. It is moreover difficult to perform soldering operations on the same positions on the front and rear faces and the contacts already soldered on one of the faces are liable to become unsoldered when soldering is performed on the other face.

FIG. 6 represents a photovoltaic module comprising only two cells 1 to simplify the drawing. The cells 1 are represented in cross-section along axis AA of FIG. 1. The strips 5 of a first cell 1a are connected to the strips 4 of the adjacent cell 1b. If the module comprises more than two cells, the strips 5 of the cell 1b are then connected to the strips 4 of the next cell, all the cells thus being connected in series. In practice, a strip 5 of a cell and the associated strip 4 of the adjacent cell are formed by a single strip. The strips 4 and 5 of the end cells act as connectors for connection to the outside. Two sheets of polymer film 8 and 9 are arranged on each side of the assembly of cells and inserted between a front glass substrate 10 and a rear glass substrate 11. To reduce the weight, certain modules do not comprise a glass substrate on the rear face, the latter then being formed by the polymer film 9.

The polymer film has a fourfold function. Firstly it provides the mechanical cohesion of the module, and forms a barrier against humidity. It further acts as index adaptation layer between the glass and silicon, thus reducing the losses by light reflection at the interfaces to the maximum. Finally, it enables heat to be removed, which is essential as the photovoltaic conversion efficiency decreases with temperature.

In document DE-A-4,128,766, the transverse metal strips are replaced by front and rear connecting conductors respectively formed on the internal face of the front glass substrate 10 and rear glass substrate 11 facing the location of each of the cells. The connecting conductors are then soldered onto the cells and onto interconnection elements designed to connect the cells in series. The space remaining between the glass substrates is then filled with an organic resin.

All known assemblies present a mediocre resistance to water vapour diffusion to the silicon, which decreases the conversion efficiency of the cells within a few years. A no more than mediocre thermal conduction of the polymer can also be noted which leads to an increase of the temperature and a reduction of the efficiency. Soldering of the strips and assembly of the cells also constitutes a handicap as they are long operations able to break the cells and result in a high production cost.

### OBJECT OF THE INVENTION

The object of the invention is to remedy these shortcomings and more particularly to provide an assembly of photovoltaic cells enabling the problems of degradation of the cell efficiency to be overcome. The assembly must preferably also have a very low manufacturing cost.

According to the invention, this object is achieved by the appended claims and more particularly by the fact that the assembly comprises a sealing joint made of an inorganic material arranged between the two glass substrates and defining a sealed internal volume wherein all the cells are contained.

According to a first development of the invention, the front and rear connecting conductors are respectively formed on the internal face of the front and rear glass substrates facing the location of each of the cells.

According to a second development of the invention, the assembly comprising at least one row of photovoltaic cells, the rear connecting conductors of all the cells of a row are formed by laser cutting of a continuous conducting strip extending between the cells and the rear substrate, the front connecting conductors of all the cells of a row being formed by laser cutting of a conducting strip tightened between the cells and the front substrate and parallel to the conducting strip forming the rear connecting conductors.

A fabrication process of an assembly according to the invention comprises a sealing operation of the assembly performed between 380° C. and 480° C. for a period of less than 30 minutes.

### BRIEF DESCRIPTION OF THE DRAWINGS

Other advantages and features will become more clearly apparent from the following description of particular embodiments of the invention, given as non-restrictive examples only and represented in the accompanying drawings, in which:

FIG. 1 represents, in top view, a photovoltaic cell according to the prior art.

FIGS. 2 and 3 respectively illustrate the front face and rear face of a cell according to the prior art before transverse metal strips are placed.

FIGS. 4 and 5 respectively illustrate the front face and rear face of a cell according to the prior art after the transverse metal strips have been placed.

FIG. 6 represents, in cross-section, a photovoltaic module according to the prior art comprising two cells according to FIG. 1, in cross-section along A-A.

FIGS. 7 and 8 respectively illustrate the front face and rear face of a particular embodiment of a cell according to the invention before encapsulation.

FIG. 9 represents, in cross-section, a first embodiment of an assembly according to the invention.

FIGS. 10 and 11 respectively represent, in top view, a front substrate (FIG. 10) and a rear substrate (FIG. 11) of an assembly according to FIG. 9.

FIGS. 12 and 13 illustrate alternative embodiments of the connecting conductors formed on the rear substrate of an assembly according to the first embodiment.

FIG. 14 represents, in top view, another particular embodiment of an assembly according to the invention.

FIG. 15 represents, in cross-section, another alternative embodiment of an assembly according to FIG. 9.

FIG. 16 represents, in top view, connection of two cells of an assembly according to a second particular embodiment of the invention.

FIG. 17 represents, in cross-section, a part of an assembly according to FIG. 16.

FIG. 18 illustrates, in top view, a module composed of 6 cells.

FIGS. 19 and 20 represent details of the module according to FIG. 18, in cross-section respectively along B-B and along C-C.

FIG. 21 illustrates an alternative embodiment of a connecting conductor for connection with the outside.

FIG. 22 represents, in top view, another particular embodiment of an assembly according to the invention.

FIG. 23 represents, in cross-section along D-D, details of the module according to FIG. 22.

FIG. 24 represents, in top view, a zone corresponding to two cells of a particular embodiment of an assembly according to the invention.

FIG. 25 represents, in cross-section along E-E, details of the module according to FIG. 24.

FIG. 26 illustrates an alternative embodiment of the assembly according to FIG. 16.

FIG. 27 illustrates another alternative embodiment of an assembly according to the invention.

FIGS. 28 and 29 illustrate in greater detail fitting of a rod through the rear substrate of an assembly according to FIGS. 15 and 20.

FIG. 30 illustrates in greater detail external connection of an assembly according to FIGS. 15 and 20.

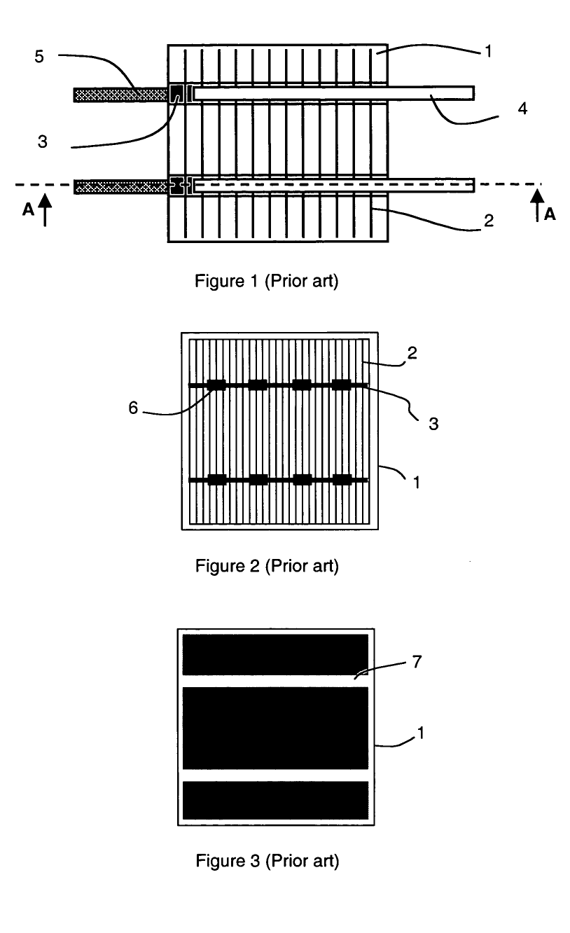

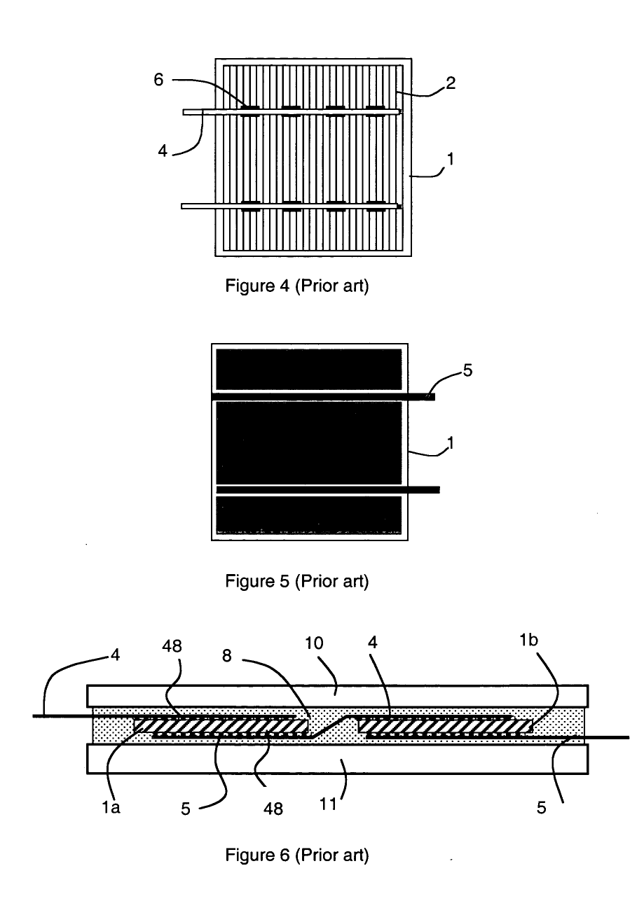

### DESCRIPTION OF PARTICULAR EMBODIMENTES.

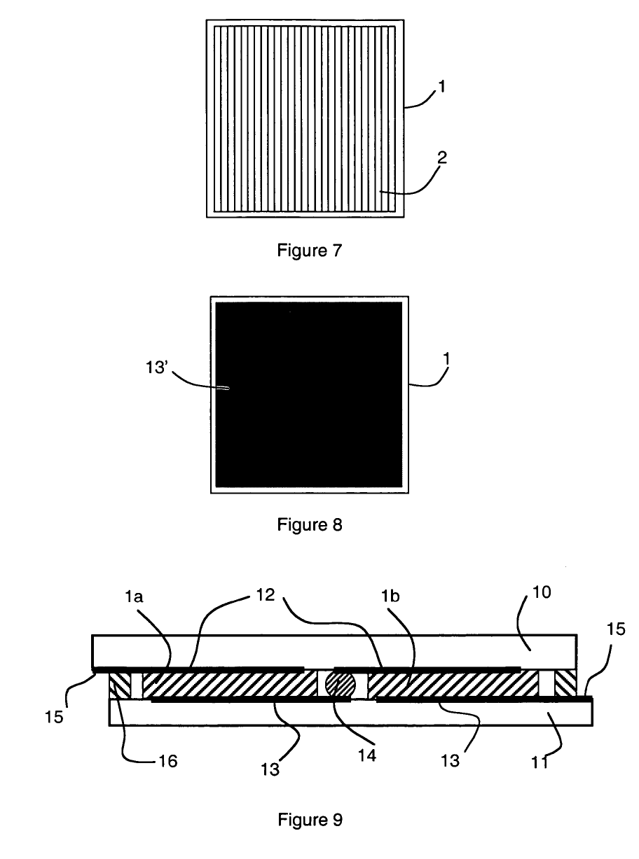

FIGS. 7 and 8 respectively illustrate the front face and rear face of a cell 1 according to the invention before encapsulation. The front face only comprises the network of fine electrodes 2, from 50 to 120 μm in width. The collector buses 3 and solder studs 6 can be eliminated, which enables the surface taken up by metallization to be reduced, and thus enables the light absorption and consequently the current and power generated by the cell to be increased while reducing the consumption of metal used, in particular silver paste. The rear face comprises a second network of electrodes, generally denser or, as represented in FIG. 8, a metal layer, preferably made of aluminium, practically covering the whole of the rear surface, which enables the performances of the cell to be increased by creation of a rear field. As the solder tracks 7 are eliminated, the cost of a cell is thus decreased both by reduction of the quantity of silver necessary and by simplification of the fabrication process. The whole of the rear face can in fact then be metallized in a single step. Moreover, the mechanical impact on the cells and the risk of breakage of cells, associated to metallization, for example by serigraphy and drying, for example in a furnace, are reduced.

The assembly according to FIG. 9, like the module of FIG. 6, comprises adjacent photo-voltaic cells 1 inserted between a front glass substrate 10 and a rear glass substrate 11. Only two cells la and lb, of the type represented in FIGS. 7 and 8, are represented in FIG. 9 for the sake of clarity.

A network of front connecting conductors 12, designed to perform the functions of the front transverse metal strips 4, is formed on the front glass substrate 10. At least one front connecting conductor 12 is arranged facing the location of each cell 1. The front connecting conductors 12 comprise a connecting zone which extends beyond one side of the location of the corresponding cell 1, to the left in the embodiment represented in FIG. 9. However the distance separating two adjacent cells is such that two adjacent front connecting conductors 12, i.e. associated to two adjacent cells, are not in contact. Likewise, a network of rear connecting conductors 13, designed to perform the functions of the rear transverse metal strips 5, is formed on the rear glass substrate 11. At least one rear connecting conductor 13 is arranged facing the location of each cell 1. The rear connecting conductors 13 each comprise a connecting zone which extends beyond the other side of the location of the corresponding cell 1, i.e. to the right in the embodiment represented in FIG. 9. There is no contact between two adjacent rear connecting conductors 13.

The assembly also comprises electrical interconnection elements 14 designed to electrically connect, between two adjacent cells (1a and 1b, etc.), the opposite connecting zones of the front connecting conductors 12 and rear connecting conductors 13 associated to two adjacent cells and respectively formed on the front glass substrate 10 and rear glass substrate 11. Connectors 15 for connection with the outside are arranged on the external connection zones of the front connecting conductors 12 and rear connecting conductors 13 of the end cells of the assembly to enable connection of the assembly with the outside.

The electrical interconnection elements 14 between the connecting electrodes of the front and rear glass substrates must enable the highest possible electrical conduction. In a preferred embodiment, they have the form of studs with a cross-section of 1 mm² to 100mm². The studs are preferably cylindrical, with a diameter of 1 mm to 10 mm, more typically from 2 mm to 4 mm. They can be obtained by deposition of a paste containing a conducting material in powder form. The conducting material can be formed by silver or silver alloy grains bonded by an inorganic binder, such as a vitreous phase. The binder can also comprise a fusible metal compound which ensures a good conduction between the silver or silver alloy grains, and possibly a small fraction of an inorganic binder such as a vitreous phase. For example, the studs can be formed from a mixture of silver particles and glass particles such as a bismuth borosilicate or a mixture of silver particles and tin-lead alloy particles. The studs can also be formed by a mixture of metal particles (at least 20%), an inorganic binder (at most 40%) and a metal (at most 80%) chosen from lead, tin or an alloy partly fusible at less than 450° C. They can further be formed by a metal alloy at least a fraction whereof is melted with an equilibrium between the liquid and solid phases at the temperature of use, i.e. at the temperature of the subsequent sealing operation, comprised between 380° C. and 480° C. Such an alloy can for example be a tin-lead-silver, tin-lead-copper or tin-lead-zinc alloy. The presence in the composition of a fraction of an alloy fusible at low temperature enables the stud to be crushed and adjusted to the required height when the sealing operation is performed, without exerting a large force on the stud.

A sealing joint 16 made of inorganic material is deposited between the front 10 and rear 11 glass substrates, at the periphery of the assembly, so as to define a sealed internal volume wherein all the cells 1 are arranged. Softening with temperature of the inorganic material constituting the joint 16 enables the front glass substrate 10 and rear glass substrate 11 to be sealed together. The sealing joint 16 has a thickness of several hundreds of microns, which depends above all on the thickness of the silicon substrates forming the cells 1, to which the thickness of the front connecting conductors 12 and rear connecting conductors 13 formed respectively on the front and rear glass substrates has to be added.

The sealing joint 16 preferably has a width comprised between 2 mm and 10 mm, more typically between 3 mm and 5 mm. It is preferably formed by a sealing glass the softening temperature whereof is as low as possible and softening with temperature whereof enables the front substrate 10 to be soldered onto the rear substrate 11. This type of product is conventional in the plasma display screen or cathode ray tube industry. It is formed for example by a lead silicate or a lead borosilicate possibly containing a few additional elements. The sealing glass is preferably of the non-crystallizable type, although this is not absolutely necessary. The granulometry of the sealing glass sinter is such that the mean diameter is comprised between 2 μm and 100 μm, more typically between 6 μm and 40 μm.

The sealing joint 16 is deposited on one of the glass substrates or on the two glass substrates 10 and 11, according to a path described below, i.e. either along the four sides or, generally, along three sides of the assembly and set back from the edge on a fourth side. The thickness of the joint 16 is from 0.2 mm to 1 mm and depends on the thickness of the cells 1 and of the connecting conductors 12 and 13.

In the course of the sealing operation, which takes place between 380° C. and 480° C. for a period of less than 30 minutes, the material of the sealing joint 16 softens greatly and makes the volume internal to the sealing joint tight with respect to the outside. Any water diffusion to the inside of the module will be prevented throughout the lifetime of the module. The pressure of the internal volume is about one atmosphere at the sealing temperature. The final pressure after cooling at ambient temperature is lower, for example about 400 millibars. A negative pressure with respect to the outside therefore forms automatically inside the assembly and results in a force being applied by the glass substrates 10 and 11 on the cells 1. This force ensures an excellent contact between the cells 1 and the front connecting conductors 12 and rear connecting conductors 13 deposited on the glass substrates without it being necessary to deposit solder between the cells 1 and the connecting conductors.

This fabrication process enables all the elements necessary for soldering to be eliminated while ensuring a high degree of protection of the cells.

According to a development of the invention, the sealed internal volume comprised between the two glass substrates 10 and 11 is filled, when the assembly operation is performed, with a mixture of one or more neutral gases chosen from nitrogen, helium, neon or argon. The mixture can also comprise hydrogen or methane. The presence of such a neutral or reducing atmosphere enables the silicon cells 1 to preserve an excellent conversion efficiency. Typically, and to prevent risks due to the presence of hydrogen or methane, the mixture comprises less than 8% of hydrogen or methane.

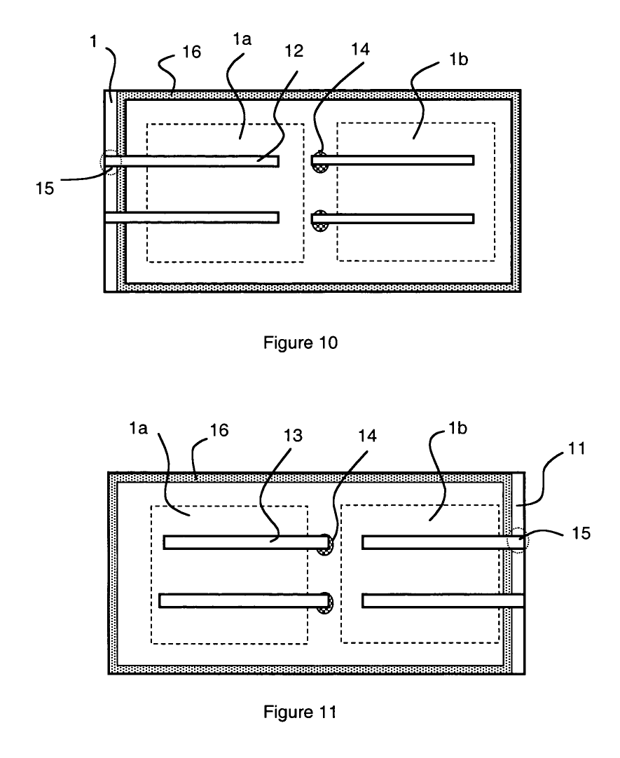

FIG. 10 represents a top view of the front glass substrate 10 with front connecting conductors 12. Two cells la and lb are represented in broken lines. A front connecting conductor 12 deposited on the front glass substrate 10 is positioned so as to come into contact with the front face of the corresponding cell 1 and comprises a connecting zone extending beyond one side of the cell (to the left in FIG. 10) to make contact with an interconnection element 14 or, for the cell situated at the left end of the assembly, with the outside via a connector 15 for connection with the outside.

In the same way, FIG. 11 represents a top view of the rear glass substrate 11 with rear connecting conductors 13 and two cells 1a and 1b represented in broken lines. A rear connecting conductor 13 deposited on the rear glass substrate 11 is positioned so as to come into contact with the rear face of the corresponding cell 1 and comprises a connecting zone extending beyond one side of the cell (to the right in FIG. 11) to make contact with an interconnection element 14 or, for the cell situated at the right end of the assembly, with the outside via a connector 15 for connection with the outside.

In the particular embodiment of FIGS. 9 to 11, the sealing joint 16 is located at the periphery of the surface common to the two glass substrates 10 and 11. It is thus arranged on the periphery of each of the glass substrates except on one side (the left side for the front glass substrate 10 and the right side for the rear glass substrate 11), to enable access from outside to the connectors 15 for connection with the outside. The connection zones of the connecting conductors 12 or 13 of the end cells are thus outwardly salient beyond the joint 16.

The pattern of the network of front connecting conductors 12 formed on the front glass substrate 10 of a cell 1 can be of any type. The surface covered by the connecting electrodes 12 must however be minimal so as to preserve a maximum optical transmission for the front substrate. Moreover, conduction must be as high as possible to reduce the ohmic losses. Each cell 1 comprises at least two front connecting conductors 12, two parallel connecting conductors 12 in the embodiment represented in FIG. 10. In a particular embodiment, the front connecting conductors 12 each have a width generally comprised between 0.2 mm and 5 mm, more typically comprised between 1.5 mm and 3 mm.

The pattern of the network of rear connecting conductors 13 formed on the rear glass substrate 11 can be of the same type as the pattern of the network of front connecting conductors. In FIG. 11 for example, each cell 1 comprises two parallel rear connecting conductors 13. However, when the rear face is not optically active, there is no constraint on the optical transmission of the rear glass substrate and the pattern of the network of rear connecting conductors is chosen in such a way that conduction is maximal. According to a first alternative embodiment, the width of the rear connecting conductors 13 is large, each rear connecting conductor 13 being able for example to have a width comprised between 3 mm and 10 mm, more typically comprised between 3 mm and 5 mm.

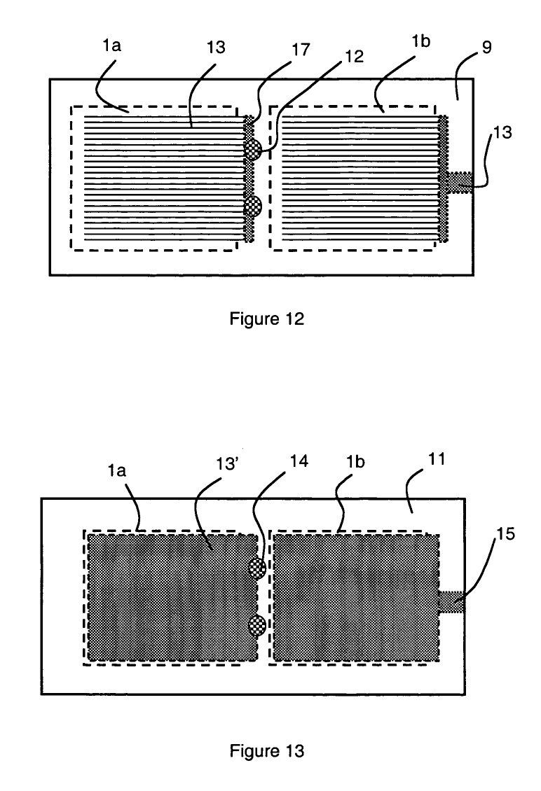

According to a second alternative embodiment represented in FIG. 12, the density of the network of rear connecting conductors 13, i.e. the number of rear connecting conductors 13 per cell 1, is greater. Thus in FIG. 12 the network of rear connecting conductors 13 is denser. Each rear connecting conductor 13 has a small width comprised between 0.5 mm and 3 mm, more typically between 1 mm and 2 mm, with a pitch of 1 mm to 10 mm, more typically of 2 mm to 4 mm. The rear connecting conductors 13 are then short-circuited by a collector electrode 17 which comes into contact with the interconnection elements 14 or a connector 15 for connection with the outside. In this case, a single connector 15 for connection with the outside is necessary on the rear glass substrate 11.

According to a third alternative embodiment, represented in FIG. 13, a rear connecting conductor 13′ covers the whole or almost the whole of the surface of the location of a cell 1.

The glass substrates 10 and 11 are preferably formed by a soda-lime glass with a thickness of 1.6 to 6 mm, a typical value being from 3 to 4 mm for the front glass substrate 10 and from 2 to 4 mm for the rear glass substrate 11. The glass is advantageously a clear or extra white glass, i.e. containing little iron, as the optical transmission of such a glass is optimal. The glass can also have undergone thermal quenching to increase its mechanical resistance.

The front connecting conductors 12 and rear connecting conductors 13 can be made of silver or of an alloy rich in silver according to a conventional process used in the display screen industry, the plasma screen industry in particular. This conventional process comprises deposition of the required pattern from a silver paste, then annealing between 400° C. and 600° C. The thickness of the front connecting conductors 12 and rear connecting conductors 13 is comprised between 2 μm and 15 μm, more typically between 4 μm and 7 μm.

According to an alternative embodiment, the known conventional process, described above, is modified and annealing following deposition of a silver paste is performed at a temperature comprised between 620° C. and 660° C. Such annealing, followed by rapid cooling as is performed for thermal quenching, enables the duration of the thermal cycle to be reduced, the resistivity of the electrode material to be greatly reduced and hardening of the glass to be obtained by thermal quenching. Consequently it is then possible not to quench the glass of the substrates 10 and 11 before deposition of the connecting conductors.

In a particular alternative embodiment, annealing is completed by a recharging operation of the connecting conductors by chemical or electrochemical means. The recharging operation is known in particular in the field of printed circuits. It consists conventionally of depositing one or more layers of a metal or a metal alloy on the existing silver or silver alloy conductors. This method enables silver conductors of small thickness to be deposited, thereby reducing the cost of the silver material. This alternative embodiment also enables annealing of the silver conductors to be performed at low temperature to degrade the organic binders initially contained in the silver paste. It does not impose high-temperature annealing of the silver paste although it is compatible with such annealing. Finally, it enables the conductivity of the conductors to be greatly increased, by chemical or electrochemical recharging, and enables them to be covered with a protective layer if required. The advantage gained from this method is therefore a large reduction of cost and an improvement of the performances of the conductors.

Silver connecting conductors with an annealed thickness of 2 μm to 3 μm can for example be deposited and annealed, a copper layer then be deposited by chemical means as is conventionally done for printed circuits, and finally a thin protective layer of nickel or silver be deposited, again by chemical means. The thickness of copper deposited can vary from 2 μm to more than 100 μm, a typical value being 50 μm. The thickness of nickel or silver deposited can vary from 0.1 μm to more than 2 μm, a typical value being 1 μm.

According to another alternative embodiment, the front connecting conductors 12 and rear connecting conductors 13 can also be achieved by a thin film technology conventionally used to achieve the electrodes of plasma display screens. The material can then be a multilayer material composed of an adhesion layer such as chromium, a conduction layer such as copper then possibly a protective layer, for example nickel or silver.

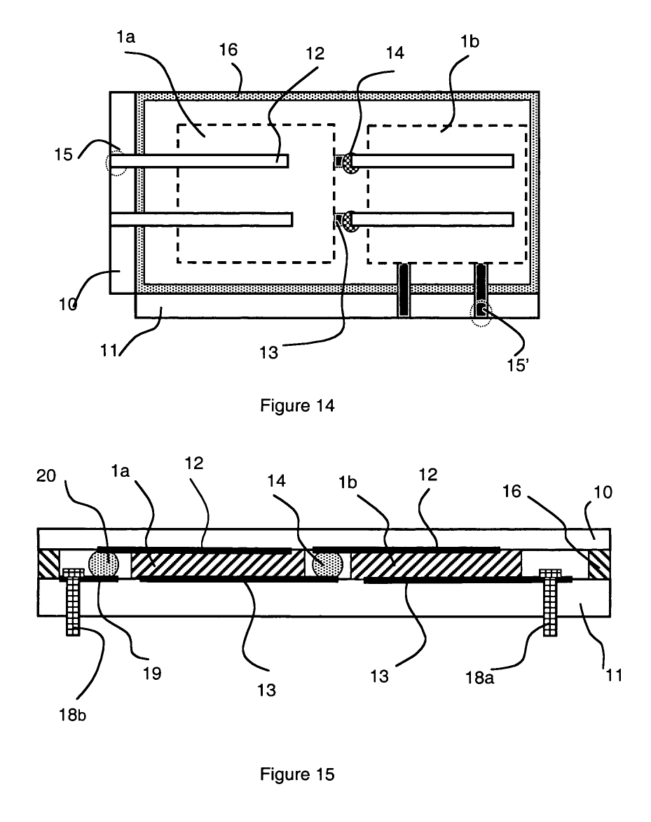

FIG. 14 illustrates, in top view, another particular embodiment of an assembly according to the invention. It differs from the embodiment of FIGS. 9 to 11 by location of the connectors for connection with the outside on the rear glass substrate 11. The connectors 15′ for connection with the outside of the rear connecting conductors 13 associated to the cell (1b) the farthest to the right are arranged on a side of the assembly that is perpendicular to the output side of the connectors 15 for connection with the outside of the front connecting conductors 12 associated to the cell (1a) the farthest to the left of the assembly. The sealing joint 16 is, as previously, arranged at the periphery of the surface common to the two substrates.

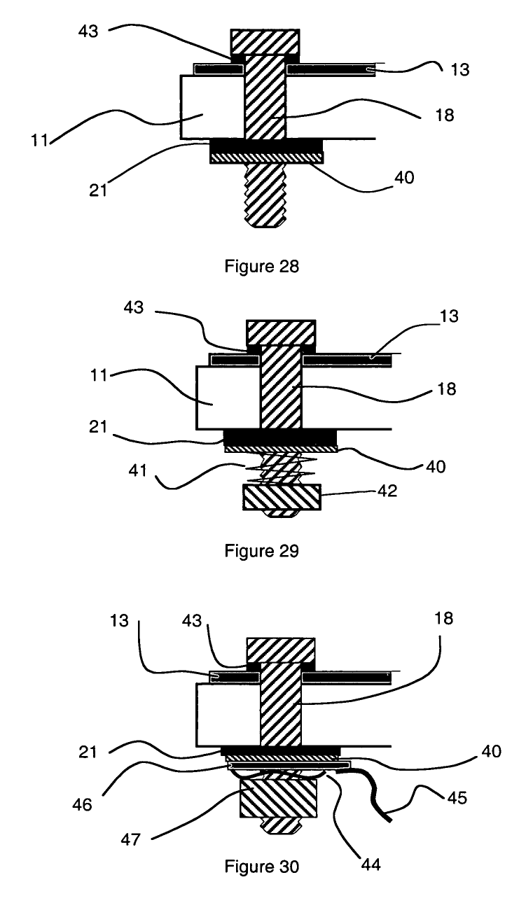

According to another embodiment, represented in FIG. 15, the connectors 15 for connection with the outside are formed by two metal rods 18 which pass in tight manner through holes of the rear glass substrate 11, and which are connected inside the assembly to the connecting conductors 12 and 13 of the end cells 1 of the assembly. In FIG. 15, the glass substrates 10 and 11 have the same dimension and are arranged facing one another. A first metal rod 18a establishes the contact with a rear connecting conductor 13 associated to the cell 1 the farthest to the right of the assembly. To establish the contact with a connecting conductor 12 of the cell 1 the farthest to the left of the assembly, an additional connecting conductor 19 is formed on the rear substrate 11 around one of the holes. It enables the contact with the front connecting conductor 12, formed on the front glass substrate 10, to be made remotely on the rear glass substrate 11 by means of an additional interconnection element 20, similar to the interconnection elements 14. A second metal rod 18b serves the purpose of establishing and of outputting the contact with the additional connecting conductor 19. A sealing joint 21 made of inorganic material, for example of the same type as the joint 16, is provided between the rods and the rear substrate (FIGS. 28 and 29). Tightness is obtained by softening of the material when the subsequent sealing operation of the assembly is performed.

Fabrication of an assembly according to the first embodiment wherein the connecting conductors are formed on the glass substrates will be described in greater detail below, for achieving an assembly containing eight 12.5 cm×12.5 cm photovoltaic cells 1 with a thickness of 200 μm.

Two 550 mm×275 mm glass substrates, for example made of soda-lime glass, are taken. One of them, designed to constitute the front glass substrate 10, is preferably made of clear soda-lime glass, i.e. containing little iron. The thickness of the glass substrates is preferably comprised between 2 mm and 4 mm (for example 3 mm). Above these values the weight becomes too great, whereas below these values the substrates are too fragile. In the particular embodiment of FIG. 15, two holes with a diameter of 4 mm are drilled in the rear glass substrate for passage of the rods 18.

To achieve the connecting conductors on the glass substrates 10 and 11, a mixture of a glass powder and 80% to 97% of a silver powder, a silver alloy, nickel copper or silver copper is prepared. The glass powder is preferably formed by lead silicate of mean granulometry comprised between 0.3 μm and 3 μm (preferably 0.5 μm) with 12% to 20% (preferably 15%) of silica. The silver paste has a mean granulometry comprised between 0.5 μm and 2 μm (preferably 1 μm). This mixture of powders is dispersed in a solution formed by propylene glycol or butylene glycol with addition of ethyl cellulose. The paste has a viscosity of 5,000 centipoises to 200,000 centipoises (preferably about 20,000 centipoises).

The connecting conductors are deposited on the glass substrates 10 and 11 by serigraphy. They are deposited in a pattern formed by strips of a length close to or slightly greater than the width of a cell 1, for example 130 mm long, on the front glass substrate 10. The number of strips associated to each cell 1 is comprised between 2 and 10, the width of a strip depending on the density of the pattern chosen. The width of a strip can thus be about 2 mm for a 2-strip pattern and about 0.2 mm for a 10-strip pattern. On the rear glass substrate 11, it is possible to achieve a full surface of 120×120 mm per cell (FIG. 13), 2 strips with a width of about 5 mm (FIG. 11), 10 strips with a width of about 1 mm or a denser fine network with strips with a width of 0.2 mm to 0.3 mm (FIG. 12). In the particular embodiment of FIG. 15, an additional connecting conductor 19 is deposited on the rear glass substrate 11 around one of the holes. After drying at 140° C. for 10 minutes in a hot air furnace, the dry thickness of the connecting conductors is comprised between 5 μm and 15 μm (preferably 12 μm).

The glass substrates are then annealed so as to make the connecting conductors adhere on the substrates and to burn the organic components contained in the deposit. This annealing is performed at a temperature of 450° C. to 680° C. for a period of 10 minutes, and may be followed by thermal quenching (at more than 600° C.) which gives the glass substrates a high mechanical strength. In the case where a recharging operation is scheduled, the dry thickness is preferably smaller, for example about 3 μm. Recharging of the connecting conductors is then performed by chemical deposition, for example of 50 μm of copper and 1 μm of silver. A reflecting layer can possibly be made on the internal face of the rear glass substrate 11, on the zones not covered by the connecting electrodes.

To achieve the interconnection elements 14 and 20, a mixture is then prepared composed of 60% to 80% of a nickel copper, silver or silver copper powder, with a mean granulometry comprised between 0.5 pm and 5 μm, and 40% to 20% of a fusible metal powder (lead or tin-lead) or glass with a low melting point (lead silicate, for example ). This mixture of powders is dispersed in a solution formed by propylene glycol with addition of ethyl cellulose. The paste has a viscosity of 50,000 centipoises to 200,000 centipoises (preferably 100,000 centipoises). The paste is deposited by serigraphy on the glass substrates, preferably on the rear glass substrate 11 only, in the form of studs with a diameter of 1 mm to 5 mm (for example 3 mm) arranged at the suitable locations. These studs are then dried at 140° C. for 10 minutes in a hot air furnace. The studs then have a dry thickness of about 200 μm, for a cell with a thickness of 175 μm to 300 μm, if the paste was deposited on the two glass substrates and about 380 μm if it was deposited on the rear glass substrate only.

The sealing glass sinter designed to form the joint 16 is then deposited. For this a sealing sinter powder of non-crystallizable type on the basis of a lead borosilicate composition, with a mean granulometry comprised between 5 μm and 100 μm (12 μm for example) and a softening temperature of 380° C. is used. This sinter is dispersed in a solution composed of propylene glycol with addition of ethyl cellulose. The paste has a viscosity of about 40,000 centipoises. A paste bead is deposited by means of a syringe at the periphery of the rear glass substrate (FIG. 15), except on one side where the bead is deposited 5 mm from the edge in the embodiments represented in FIGS. 9 to 14. In an alternative embodiment, the paste is deposited on both substrates. This does however require both substrates to then be dried and annealed, which is more costly. The bead thus formed is dried at 140° C. for 10 minutes in a hot air furnace. The dry thickness of the bead depends on the thickness of the cells 1, typically comprised between 300 μm and 400 μm, and its width is comprised between 3 mm and 6 mm. The rear glass substrate is then annealed at 400° C. for 10 minutes.

The cells 1 are then placed on the rear glass substrate 11. In the particular embodiment of FIG. 15, fitting of the connections through the substrate is then performed (FIG. 29). This assembly is preferably placed in a volume whose atmosphere is a mixture of nitrogen and hydrogen comprising from 0% to 8% of hydrogen and wherein the front glass substrate 10 is positioned. Grips are placed on the periphery of the assembly so as to apply a crushing force on the sealing bead. The assembly is then heated to a temperature comprised between 410° C. and 460° C. for 10 minutes so as to seal the two substrates. In an alternative embodiment, the assembly is assembled in the air before being placed in a furnace in which a vacuum of 10 millibars is created and which is then filled with a mixture of nitrogen and hydrogen before heating. After cooling, the grips are removed. The assembly is then ready to be integrated in a generator.

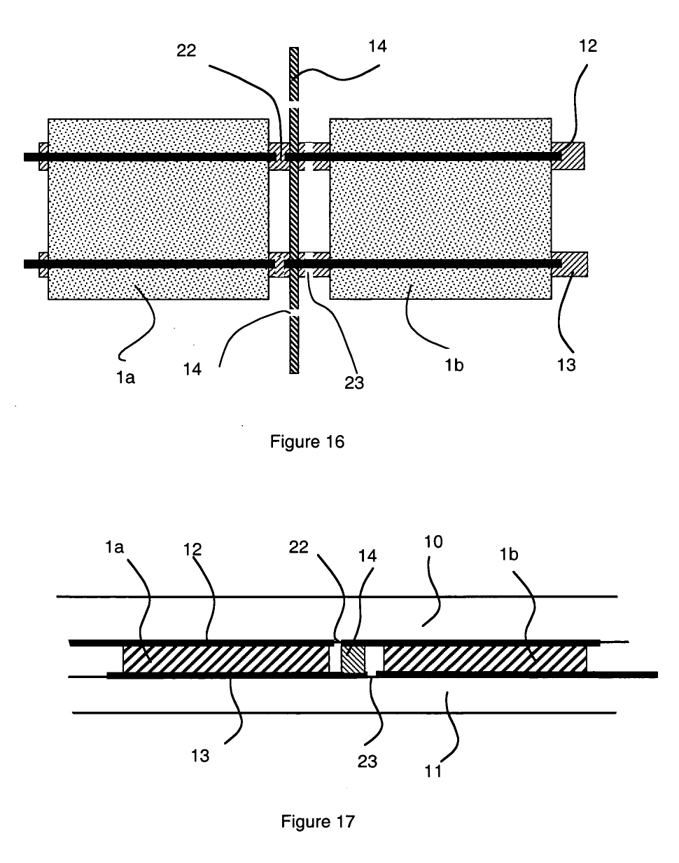

In the particular embodiment represented in FIG. 16, the connecting conductors 12 and 13 are not formed on the glass substrates. The rear connecting conductors 13 of all the cells of a row of the assembly are formed by laser cutting of tightened continuous conducting strips located between the cells 1 and rear substrate 11. In similar manner, the front connecting conductors 12 of all the cells of a row are formed by laser cutting of tightened continuous conducting strips located between the cells 1 and front substrate 10 and parallel to the conducting strips forming the rear connecting conductors. Two conductors 12 associated to adjacent cells and formed by cutting of a conducting strip are aligned and separated by a space 22. There is therefore no electrical continuity between the conductors 12 associated to two adjacent cells. In similar manner, two conductors 13 associated to two adjacent cells are aligned and separated by a space 23.

As previously, a sealing joint 16 is arranged between the front glass substrate 10 and rear glass substrate 11, at the periphery of the assembly, so as to define an internal sealed volume wherein all the cells 1 are arranged. As previously, a negative pressure with respect to the outside forms automatically inside the assembly in the course of the sealing operation and results in a force being applied by the glass substrates 10 and 11 on the connecting conductors 12 and 13. These connecting conductors 12 and 13 in turn press on the interconnection elements 14 and cells 1. This force ensures an excellent contact between the interconnection elements 14 and connecting conductors 12 and 13 on the one hand and between the cells 1 and connecting conductors 12 and 13 on the other hand. In the case where a soldering material, for example tin or a tin-lead or tin-lead-silver alloy, has been deposited on the surface of the interconnection elements 14, a solder is obtained between the connecting conductors 12 and 13 and interconnection elements 14.

An assembly can comprise several rear connecting conductors 13 per cell 1, typically 2 to 5 conductors for cells of dimensions comprised between 100 mm×100 mm and 200 mm×200 mm, and several conductors 12 per cell 1, typically 2 to 5 conductors for cells of dimensions comprised between 100 mm×100 mm and 200 mm×200 mm.

The rear connecting conductors 13 are formed by a flat metal conductor, generally made of copper, which may be covered with another metal such as tin or silver, or tin-lead or tin-lead-silver alloys. The width of these conductors is comprised between 0.5 and 8 mm, typically 4 mm. Their thickness is comprised between 0.05 and 0.3 mm, typically 0.10 mm. The front connecting conductors 12 are formed by a flat metal conductor, generally made of copper, which may be covered with another metal such as tin or silver, or tin-lead or tin-lead-silver alloys. The width of these conductors is comprised between 0.5 and 5 mm, typically 2 mm. Their thickness is comprised between 0.05 and 0.3 mm, typically 0.12 mm.

Interconnection elements 14 are, as previously, arranged between two adjacent cells so as to electrically connect the connection zone of a front connecting conductor 12 associated to a cell 1a and the connection zone of a rear connecting conductor 13 associated to an adjacent cell 1b (FIGS. 16 and 17). In FIG. 16, a front connecting conductor 12 and rear connecting conductor 13 are arranged facing one another, on each side of each cell 1, the connecting conductor 13 being salient to the right of the cell and the connecting conductor 12 being salient to the left of the cell. The interconnection elements 14 are formed by a flat metal conductor, generally made of copper, which may be covered with another metal such as tin or silver, or tin-lead, tin-silver or tin-lead-silver alloys. The width of the interconnection elements 14 is comprised between 0.5 mm and 5 mm, typically 1.5 mm. Their thickness depends on the thickness of the cells 1 and is generally comprised between 0.15 mm and 0.5 mm, typically 0.3 mm.

In the embodiment represented in FIG. 16, each cell is associated to two front connecting conductors 12 and two rear connecting conductors 13. The front connecting conductors 12 associated to one and the same cell are electrically interconnected by means of the interconnection element 14 to which their respective connection zones are connected. The same is the case for the conductors 13 associated to one and the same cell.

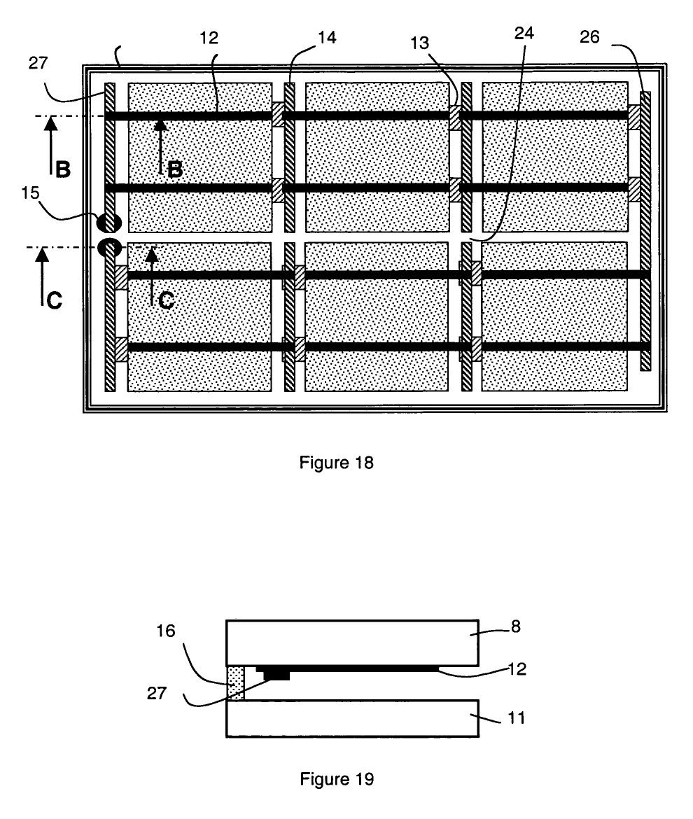

FIG. 18 shows an example of assembly of six cells in two rows of three cells, thus forming three columns of two cells. In the embodiment represented in FIG. 18, the connection zones of the rear connecting conductors 13 of the cells of the first row are arranged on the right of the cell, as in FIG. 16, whereas the connection zones of the rear connecting conductors 13 of the cells of the second row are arranged on the left of the cell. Interconnection elements 14 are arranged between two columns. Two interconnection elements 14 associated to adjacent cells of the same column are aligned and separated by a space 24.

The aligned rear connecting conductors 13 of the cells belonging to the same row are formed by cutting a continuous conducting strip. The conducting strips are cut by laser at the locations of the spaces 23. Thus, a conducting strip designed to form the aligned rear connecting conductors 13 of cells of the same row is cut beyond the connection zone of each rear connecting conductor 13 involved and its connection with an interconnection element 14, so as to break the electrical continuity between the rear connecting conductors 13 of two juxtaposed cells. In the same way, the aligned front connecting conductors 12 of the cells belonging to the same row are formed by cutting a conducting strip. The conducting strips are cut by laser at the locations of the spaces 22. Thus, a conducting strip designed to form the aligned front connecting conductors 12 of cells of the same row is cut beyond the connection zone of each front connecting conductor 12 involved and its connection with an inter-connection element 14, so as to break the electrical continuity between the front connecting conductors 12 of two juxtaposed cells.

Formation of the connecting conductors 12 and 13 is achieved by cutting after positioning of the cells 1 between the conducting strips designed to form the conductors 12 and 13.

In like manner, the aligned interconnection elements 14 arranged between two adjacent columns can be formed by cutting a continuous conducting strip. For this, a continuous conducting strip designed to form the interconnection elements 14 arranged between two adjacent conductors is cut between two rows of cells, at the locations of the spaces 24, so as to break the electrical continuity between two rows of cells.

In FIG. 18, a row interconnection conductor 26 is placed on one side of the assembly of cells (to the right in FIG. 18) to perform connection between the two rows of cells. The row interconnection conductor 26 connects the rear connecting conductors 13 of the last cell of the first row to the front connecting conductors 12 of the last cell of the second row. If the assembly comprises more than two rows of cells, row interconnection conductors 26 are placed on both sides of the cell assembly so as to connect on the one hand the rear connecting conductors 13 of the last cell of a row of odd order to the front connecting conductors 12 of the last cell of the next row and, on the other hand, the rear connecting conductors 13 of the first cell of a row of even order to the front connecting conductors 12 of the first cell of the next row.

In FIG. 18, two conductors 27 for interconnection with the outside, placed on the other side of the assembly (to the left in FIG. 18), are respectively designed to perform connection of the front connecting conductors 12 of the first cell of the first row and of the rear connecting conductors 13 of the first cell of the second row with two conductors 15 for interconnection with the outside. If the assembly comprises an odd number of rows, a conductor 27 for interconnection with the outside is arranged on each side of the cell assembly so as to connect the end cells of the assembly, i.e. the front connecting conductors 12 of the first cell of the first row and the rear connecting conductors 13 of the last cell of the last row, to the two connectors 15.

FIG. 19 shows in greater detail, in a cross-section along BB, the connection between the connection zone of a front connecting conductor 12 of a cell situated at one end of the assembly and the conductor 27 for interconnection with the outside.

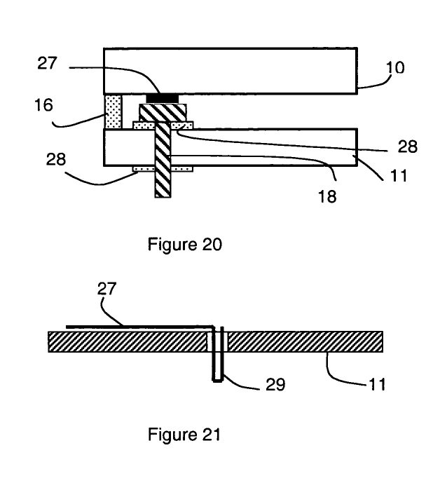

In FIG. 20 the connector 15 is formed, as in FIG. 15, by a metal rod 18 that presents a flat head and passes tightly through a hole of the rear glass substrate 11. The metal rod 18 is connected inside the assembly to the conductor 27 for interconnection with the outside and is preferably fixed onto the rear substrate 11 by sticking or soldering elements 28 on both sides of the rear substrate. The elements 28 are preferably made of inorganic material whose softening with temperature enables soldering between the connectors and the substrate during the assembly sealing operation. The diameter of the holes drilled in the rear glass substrate 11 can range from 1 mm to 12 mm, more typically from 2 mm to 5 mm. The metal rods 18 are preferably made of a good electrical conducting material, for example copper. They are advantageously coated with a thin layer of a metal that does not oxidize easily, for example nickel, silver or gold.

In an alternative embodiment, the module does not have any conductors 27 for interconnection with the outside or any connectors 15. The rear connecting conductors 13 of the cell of one end of the assembly and the front connecting conductors 12 connected to the cell of the opposite end of the assembly are then extended beyond the sealing joint 16 and pass through the latter. These extended connecting conductors 12 and 13 then act as connectors to the module.

The conductors 27 for interconnection with the outside can, as represented in FIG. 21, also act as connectors 15 with the outside. The conductor 27 is then preferably made of a thick strip having for example a thickness of 0.1 mm to 0.5 mm, typically 0.4 mm. This thick strip is folded so as to form a U-shaped zone 29 passing through a hole of the rear glass substrate 11 so as to make a connection with the outside. Tightness of the passage of the strip through the hole is ensured by a sealing glass. Outputs of this type can be used to form intermediate outputs of the assembly between the connectors 15, in particular to enable the cells to be protected by diodes. As the voltage acceptable by protection diodes is limited to a few volts or a few tens of volts, a protection diode is generally provided every 6 to 8 cells, thus requiring the presence of intermediate outputs.

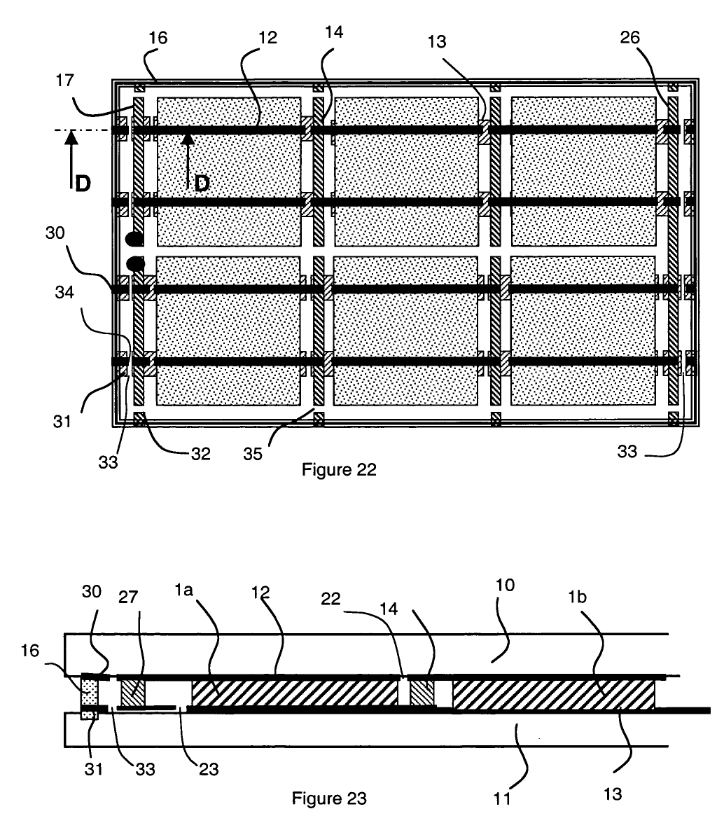

In the particular embodiment of FIGS. 22 and 23 which illustrates a geometry that can be obtained when the connecting conductors 12 and 13 and the interconnection elements 14 are formed by cutting continuous conducting strips, residual elements, respectively 30, 31 and 32, of the continuous conducting strips pass through the sealing joint 16. They are electrically insulated from the connecting conductors and from the interconnection elements, respectively 12, 13 and 14, by spaces, respectively 33, 34 and 35.

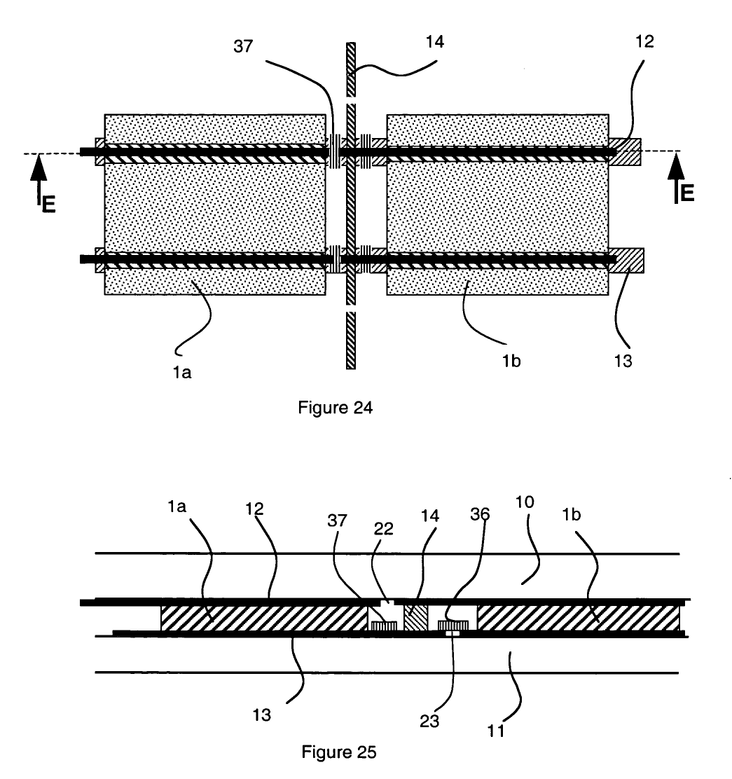

In an alternative embodiment schematized in FIGS. 24 and 25, a layer of inorganic material is deposited on the conducting strips designed to form the rear connecting conductors 13 in zones that are neither facing the cells 1 nor facing the interconnection elements 14, so as to form stops 36 covering the locations of the spaces 23 of the rear connecting conductors 13 and stops 37 covering the locations situated opposite the locations of the spaces 22 of the front connecting conductors 12. The inorganic material constituting this layer can be an agglomerate inorganic powder. The purpose of the stops 36 and 37 is to protect the conducting strips respectively arranged facing the spaces 23 and 22 when the latter are cut by laser.

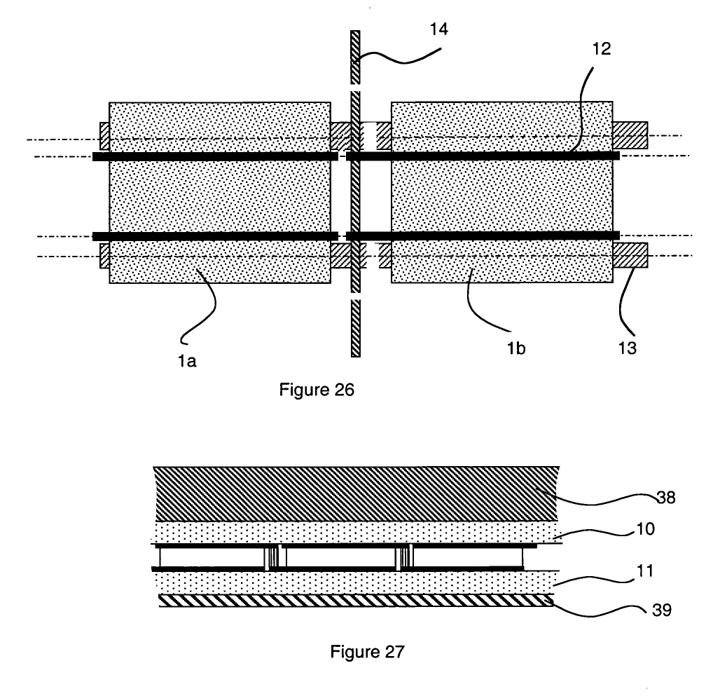

The interconnection elements 14 can be formed by interconnection studs arranged between the connection zones of the connecting conductors 12 and 13 to be connected. When the interconnection elements 14 are formed by conducting strips, the connecting conductors 12 and 13 to be connected may not be arranged facing one another, as in FIG. 16, but be offset as illustrated in the alternative embodiment of FIG. 26.

An assembly of photovoltaic cells according to FIGS. 16 to 26 can be fabricated in the manner described below. The two glass substrates 10 and 11 are prepared, a sealing sinter 16 being deposited on their periphery and this deposit being pre-annealed. On the rear glass substrate 11, conducting strips of equal cross-section to those of the future rear connecting conductors 13 are placed at the location of these future conductors 13. Likewise, conducting strips of equal cross-section to those of the future interconnection elements 14 are tightened onto the first conducting strips at the location of the future interconnection elements 14. The photo-voltaic cells 1 are then fitted in place, then conducting strips of equal cross-section to that of the future front connecting conductors 12 are tightened on the cells at the location of these future conductors 12. The front glass substrate 10 is finally fitted in place. Grips are placed around this assembly to maintain a pressure on the sealing sinter 16. Cutting of the conducting strips extending beyond the substrates is then performed, and sealing annealing of the two glass substrates is then performed. In a last step, the conducting strips are cut by laser through the glass substrates to connect the photovoltaic cells in series. Cutting of the conducting strips designed to achieve the rear connecting conductors 13 is performed through the rear substrate 11, whereas cutting of the conducting strips designed to achieve the front connecting conductors 12 is performed through the front substrate 10.

In an alternative embodiment, a layer of inorganic material designed to form the stops 36 and 37 is deposited (FIGS. 24 and 25) after the photovoltaic cells have been fitted, before the conducting strips designed to form the front connecting conductors 12 are placed and the front glass substrate 10 is fitted. The presence of the stops 36 and 37 enables the connecting conductors 12 and 13 to be cut easily, by laser ablation, at the interruption points formed by the spaces 22 and 23 without any risk of damaging the conductor situated facing the latter. When the rear connecting conductors 13 are cut by laser through the rear glass substrate 11, the laser beam cutting the conducting strip so as to form a space 23 between two rear connecting conductors 13 is in fact stopped by the stop 36 arranged above the location of this space on the conducting strip to be cut. The zone of the conducting strip designed to form the front connecting conductors 12 arranged facing the latter is thus protected. Likewise, the stop 37 arranged on the conducting strip designed to form the rear connecting conductors 13 facing the location of the space 22 to be cut protects this conducting strip when the space 22 is cut through the front glass substrate 10.

In another alternative embodiment of the process, the conducting strips are cut by laser after the clamping grips of the substrates have been fitted and before sealing annealing is performed.

Fabrication of an assembly according to the particular embodiment of FIG. 22 will be described in greater detail below for achieving an assembly containing four rows of six cells, i.e. twenty-four 15 cm×15 cm photovoltaic cells 1 with a thickness of 300 μm.

The sealing glass sinter is deposited on the rear glass substrate as in the previous example. The connectors 15 are then fitted and the elements 28 designed for sealing are fitted in place around the connectors 15. The connectors 15 are covered with a thin layer of tin with a thickness of 2 μm.

To achieve the rear connecting conductors 13, first copper conducting strips of rectangular cross-section are tightened on the rear substrate 11 with a spacing between the conducting strips which corresponds to the spacing between the rear connecting conductors 13 of the cells 1. The width of these conducting strips is 4 mm and their thickness is 0.10 mm. To achieve the interconnection elements 14, second copper conducting strips of rectangular cross-section are tightened on the first strips, perpendicularly to the first strips so as to place a second conducting strip at the locations provided between each pair of cells of one and the same row. The same procedure is performed to achieve the row interconnection conductors 26 and the conductors 27 for interconnection with the outside at the end of the rows. The width of these second conducting strips, made of copper covered with a thin layer of tin with a thickness of 2 μm, is 1.5 mm and their thickness is 0.3 mm. The cells 1 are then deposited on the first conducting strips and between the second conducting strips.

Studs of a paste with a viscosity of 80,000 centipoises and composed of 80% mass of alumina charge and 20% mass of solvent are then deposited by means of a syringe dispenser on the first conducting strips between the second conducting strips and the cells 1 to form the stops 36 and 37. Oblong studs 4 mm long, 1 mm wide and 200 μm thick are formed. The solvent is for example an alcohol such as isopropanol.

To achieve the front connecting conductors 12, third copper conducting strips of rectangular cross-section are tightened on the cells 1 and the second conducting strips so as to have a third conducting strip vertical to each of the first conducting strips. The width of these third conducting strips is 2 mm and their thickness is 0.13 mm.

The front glass substrate 10 is then deposited on the front connecting conductors 12, this operation being performed in a nitrogen atmosphere. Grips are placed around the glass substrates 10 and 11 to maintain a clamping force and form a prepared assembly. The conducting strips are then cut flush with the substrates. This prepared assembly is then placed on the belt of a conveyor furnace whose atmosphere is composed of nitrogen and is controlled by continuous nitrogen injection. The furnace performs heating to 420° C. in half an hour and maintains this temperature of 420° C. for 5 minutes. The cooling zone of the furnace then performs cooling of the prepared assembly in half an hour.

After cooling, the grips are removed and the conducting strips are cut by laser to form the spaces 22 and 23, facing the studs 37 and 36, and the spaces 24 so as to define the connecting conductors 12 and 13 and the interconnection elements 14.

In the alternative embodiment illustrated in FIG. 27, the thickness of the glass substrates is reduced, which enables the weight of the assembly to be reduced. Each glass substrate has a thickness comprised between 0.5 mm and 2 mm, typically between 0.8 mm and 1.6 mm, and preferably 1.2 mm. The front and rear glass substrates 10 and 11 preferably have the same thickness. The thermal treatment operations, and in particular sealing, are more efficient and less costly as the mass of glass to be heated is smaller. In the previous embodiments, the front glass substrate was quenched to resist shocks, for example hail. In the alternative embodiment of FIG. 27, the front and rear glass substrates 10 and 11 are not quenched. The mechanical strength of the module, in particular its resistance to shocks, is nevertheless ensured by front and rear protective layers 38 and 39 achieved after the sealing operation, respectively on the external faces of the front and rear glass substrates. The front protective layer 38 is transparent and can be formed by lamination of a transparent polymer film, by projection of a transparent plasticizing finish or by fixing, for example by sticking or clamping, of a sheet of tempered glass or a sheet of polymer (polycarbonate, PMMA, etc.). The rear protective layer 39 can be formed by lamination of a polymer film, by projection of a transparent plasticizing finish or by fixing, for example by sticking or clamping, of a sheet of tempered glass or a sheet of polymer (polyethylene, PVC., etc.). The final weight of the assembly is reduced due to the reduction of the thickness of the glass substrates. For example, glass substrates with a thickness of 4 mm can be replaced by glass substrates 10 and 11 with a thickness of 1 mm, a front protective layer 38 of tempered glass with a thickness of 3 mm and a rear protective layer 39 formed by a polymer film, reducing the thickness of the glass layers of the assembly to 5 mm while guaranteeing a good protection.

The rods 18a and 18b of FIG. 15 and 18 of FIG. 20 are advantageously provided with a head and can be achieved in the form of a screw, i.e. bear a thread over at least a part of their length. The diameter of the two holes drilled in the rear glass substrate 11 can range from 1 mm to 12 mm, more typically from 2 mm to 5 mm. A metal rod 18 has a diameter 0.1 mm to 2 mm smaller than that of the drilled hole. A rear connecting conductor 13 and the additional connecting conductor 19 are deposited around each of these two holes. The metal rods 18 are preferably made of good electrical conducting material, for example copper. They are advantageously coated with a thin layer of a metal that does not oxidize easily, for example nickel, silver or gold. They can also receive two different layers, one localized on the head of the rod to provide a good electrical contact with the associated connecting conductor 13 or 19, and a second one arranged on the body of the rod, and the thread if applicable, to resist oxidation. A rod 18 can for example be formed by a copper body with a head covered with a thin layer of silver with a thickness of 0.1 pm to 100 μm (typically 10μm) and a thread covered with a thin layer of nickel with a thickness of 0.1 μm to 100μm (typically 1 μm).

The tightness between the rear glass substrate 11 and a rod 18 is obtained (FIGS. 28 and 29) by the sealing joint 21 made of pre-sintered sealing glass. The joint 21 is advantageously associated with a washer 40 made of nickel copper. FIG. 29 illustrates fitting of the rod 18 during the sealing operation. The washer 40, whose function is to press the sealing material against the bottom face of the rear glass substrate 11 and rod 18, is then subjected to the action of a spring 41 itself held and compressed by a nut 42. The spring 41 and nut 42 are removed after the sealing operation. A second washer 43, made of very fusible conducting material, for example lead or a lead-tin alloy, can be added between the head of the rod 18 and the associated connecting electrode 11 or 19. The function of this second washer 43 is to ensure a good electrical contact between the connecting electrode and rod and to improve the tightness of the assembly.

FIG. 30 illustrates the assembly obtained after the sealing operation and completed by the elements necessary to achieve external connection. A spade connector 44, to which connecting wires 45 can be soldered, is arranged around the external part of the rod. The spade connector 44 is preferably pressed against the washer 40 by a spring 46 itself kept clamped by any suitable means, for example by a nut 47 screwed onto the thread of the rod 18.

In an advantageous embodiment, a layer of pulverulent material is placed, after formation of the rear connecting conductors 13, on the zones of the rear glass substrate 11 that are not covered by the rear connecting conductors 13. Such a layer enables the forces to be well distributed when the sealing operation of the assembly is performed.

According to another development of the invention, a reflecting layer is arranged on the internal face of the rear glass substrate 11. A large part, often more than 50%, of the incident light that strikes the assembly between the cells 1, is reflected to the front by this reflecting layer. Due to the reflecting layer, the reflected light is partly redirected to the sensitive surface of the cells 1 and therefore participates in increasing the conversion efficiency of the module. The reflecting layer can notably be formed by the layer of pulverulent material mentioned above.

The force distribution layer or the reflecting layer is preferably a very porous layer. In a preferred embodiment, it is formed by grains of a ceramic material, for example an aluminium oxide, titanium oxide, silica oxide, or any other oxide, with a granulometry such that the mean diameter is comprised between 0.3 μm and 20 μm, more typically between 0.6 μm and 8 μm. The thickness of the layer is about 5 μm to 50 μm, typically comprised between 8 μm and 25 μm.

In an alternative embodiment, the reflecting layer is formed by a diffusing layer, which can be white, formed on the glass used to constitute the rear glass substrate 11. In the embodiment of FIG. 16, the thickness of the reflecting layer is of the same order of magnitude as the thickness of the rear connecting conductors 13. The reflecting layer can be deposited on the rear substrate before pre-annealing of the sealing sinter.

The essential advantage of an assembly according to the invention is a perfect tightness that gives it a lifetime of several tens of years in wet environments. The assembly according to the invention also enables modules to be achieved with a very low production cost.

Another advantage of the assembly according to the invention lies in its high thermal conductivity which enables heat to be removed and a relatively low temperature to be maintained, which in turn enables a good conversion efficiency of the photovoltaic cells to be preserved.

The assembly according to the invention can be applied to achieving photovoltaic modules, then solar generators, from square, rectangular or round photovoltaic cells whose characteristic dimensions can range from a few centimeters to several tens of centimeters. The cells are preferably square cells whose side is comprised between 8 cm and 30 cm.

The invention is not limited to the particular embodiments described and represented above. In particular, it applies to any type of photovoltaic cells, not only to silicon-based, monocrystalline or polycrystalline photovoltaic cells, but also gallium arsenide cells, cells formed by silicon strips, silicon ball cells formed by a network of silicon balls inserted in conducting sheets, or photovoltaic cells formed by deposition and etching of a thin layer of silicon, copper/indium/selenium or cadmium/tellurium on a glass or ceramic substrate. In this case, the cells can be formed directly on the front glass substrate 10 whereon the front connecting conductors 12 and interconnection elements 14 have been previously formed.

1-32. (cancelled).

33. Assembly of photovoltaic cells arranged side by side between front and rear glass substrates and connected in series by front and rear connecting conductors respectively arranged on each side of each of the cells and comprising a connecting zone extending beyond a predetermined side of said location, the assembly comprising electrical interconnection elements arranged between two adjacent cells to connect the opposite connecting zones of the front and rear connecting conductors respectively associated to two adjacent cells, said assembly comprising a sealing joint made of an inorganic material arranged between the two glass substrates and defining a sealed internal volume wherein all the cells are contained.

34. Assembly according to claim 33, wherein the sealed internal volume is filled with a neutral gas or a mixture of neutral gases chosen from nitrogen, helium, neon or argon.

35. Assembly according to claim 34, wherein the mixture comprises hydrogen or methane in a quantity smaller than 8%.

36. Assembly according to claim 33, wherein the sealing joint is an inorganic glass with a low softening point.

37. Assembly according to claim 33, wherein the sealing joint comprises lead silicate or lead borosilicate.

38. Assembly according to claim 33, wherein the sealing joint has a width comprised between 2 mm and 10 mm.

39. Assembly according to claim 33, wherein the sealing joint is arranged at the periphery of the opposite surfaces of the glass substrates.

40. Assembly according to claim 39, wherein the front and rear glass substrates do not overlap totally, the connection zones of the connecting conductors associated to cells arranged at the ends of the assembly passing through the sealing joint.

41. Assembly according to claim 33, wherein the front and rear connecting conductors are respectively formed on the internal face of the front and rear glass substrates, facing the location of each of the cells.

42. Assembly according to claim 41, wherein the rear glass substrate comprises a connecting conductor associated to each cell and covering substantially the whole of the surface corresponding to the location of said cell.

43. Assembly according to claim 41, wherein the interconnection elements have the form of studs with a cross-section of 1 mm² to 100 mm².

44. Assembly according to claim 41, wherein the interconnection elements are formed by deposition, on at least one of the glass substrates, of a paste comprising a powder-based conducting material.

45. Assembly according to claim 44, wherein the paste forming the interconnection elements is formed by a mixture of metallic particles, an inorganic binder and a metal chosen from lead or tin.

46. Assembly according to claim 44, wherein the paste forming the interconnection elements is formed by a mixture of metallic particles, an inorganic binder and an alloy fusible at less than 450° C.

47. Assembly according to claim 33, wherein the assembly comprising at least one row of photovoltaic cells, the rear connecting conductors of all the cells of a row are formed by laser cutting of a continuous conducting strip tightened between the cells and rear substrate, the front connecting conductors of all the cells of a row being formed by laser cutting of a continuous conducting strip tightened between the cells and front substrate, parallelly to the conducting strip forming the rear connecting conductors.

48. Assembly according to claim 47, wherein the interconnection elements are formed by laser cutting of continuous conducting strips tightened between the photovoltaic cells, perpendicularly to the front and rear connecting conductors.

49. Assembly according to claim 47, wherein the interconnection elements are covered with a thin layer of a material chosen from tin, silver, tin-lead, tin-silver or tin-lead-silver.

50. Assembly according to claim 47, comprising several rows of cells, a row interconnection conductor being placed on one side of the assembly so as to connect the front connecting conductors of an end cell of a row to the rear connecting conductors of the adjacent end cell of another row.

51. Assembly according to claim 47, comprising a layer of inorganic material deposited on the conducting strips designed to form the rear connecting conductors in zones which are neither facing the cells nor facing the interconnection conductors, so as to form stops covering the locations situated facing the spaces cut by laser between the connecting conductors.

52. Assembly according to claim 47, wherein conductors for interconnection with the outside are arranged so as to perform connection of the front or rear connecting conductors of a cell with the outside of the assembly.

53. Assembly according to claim 33, wherein at least one rear connecting conductor of a cell of one end of the assembly and at least one front connecting conductor of a cell of the opposite end of the assembly are extended and pass through the sealing joint.

54. Assembly according to claim 33, comprising connectors designed to enable connection of the assembly with the outside and electrically connected to connecting conductors of the cells to be connected, a connector being formed by a metal rod passing tightly through the rear glass substrate.

55. Assembly according to claim 54, wherein an inorganic glass with a low softening point performs sealing between the metal rods and the rear glass substrate.

56. Assembly according to claim 33, wherein a layer of pulverulent material is formed on the zones of the rear glass substrate that are not covered by the rear connecting conductors.

57. Assembly according to claim 33, wherein the rear connecting conductors are wider than the front connecting conductors.

58. Assembly according to claim 33, comprising several parallel front connecting conductors associated to each cell and several parallel rear connecting conductors associated to each cell.

59. Assembly according to claim 33, wherein the front and rear connecting conductors of one and the same cell are laterally offset with respect to one another.

60. Assembly according to claim 33, wherein the glass substrates having a thickness comprised between 0.5 mm and 2 mm, the assembly comprises a front and rear protective layer respectively formed on the front and rear glass substrate after sealing of the assembly.

61. Fabrication process of an assembly according to claim 33, wherein a sealing operation of the assembly is performed between 380° C. and 480° C. for a period of less than 30 minutes.

62. Process according to claim 61 for achieving the assembly wherein the front and rear connecting conductors are respectively formed on the internal face of the front and rear glass substrates, facing the location of each of the cells, wherein the connecting conductors are formed by deposition of a silver paste on one of the glass substrates, followed by annealing, annealing being performed at a temperature comprised between 620° C. and 660° C. and followed by a recharging operation of the connecting electrodes by chemical or electrochemical means.

63. Process according to claim 61 for achieving the assembly wherein the assembly comprises at least one row of photovoltaic cells, the rear connecting conductors of all the cells of a row are formed by laser cutting of a continuous conducting strip tightened between the cells and rear substrate, the front connecting conductors of all the cells of a row being formed by laser cutting of a continuous conducting strip tightened between the cells and front substrate, parallelly to the conducting strip forming the rear connecting conductors, wherein conducting strips of cross-section respectively equal to that of the future connecting conductors and interconnection elements are tightened at the location of the future connecting conductors, the conducting strips being cut by laser through the glass substrates to connect the photovoltaic cells in series.

64. Process according to claim 63, wherein conducting strips of equal cross-section to that of the future interconnection elements are tightened at the location of the future interconnection elements.
